(19) United States
(12) Patent Application Publication
(10) Pub. No.: US 2025/0069663 A1
(43) Pub. Date: Feb. 27, 2025

(54) MEMORY DEVICE FOR PERFORMING A PROGRAM OPERATION AND AN OPERATING METHOD OF THE MEMORY DEVICE

(71) Applicant: SK hynix Inc., Icheon-si Gyeonggi-do (KR)

(72) Inventor: Chi Wook AN, Icheon-si Gyeonggi-do (KR)

(73) Assignee: SK hynix Inc., Icheon-si Gyeonggi-do (KR)

(21) Appl. No.: 18/632,972

(22) Filed: Apr. 11, 2024

(30) Foreign Application Priority Data
Aug. 24, 2023 (KR) 10-2023-0111350

(51) Int. Cl. G11C 16/10; G11C 16/04; G11C 16/08; G11C 16/34

(52) U.S. Cl. CPC G11C 16/10; G11C 16/0483; G11C 16/3459; G11C 16/08

(57) ABSTRACT

A memory device includes: a plurality of memory cells; a peripheral circuit for performing a program operation of storing data in the plurality of memory cells; and a program operation control circuit for, in the program operation, controlling the peripheral circuit to perform a foggy program operation of increasing a threshold voltage of the plurality of memory cells to a threshold voltage corresponding to any one state among an erase state and first to sixth foggy program states, and perform a fine program operation of increasing the threshold voltage of the plurality of memory cells to any one state among the erase state and first to fifteenth fine program states.

### CROSS-REFERENCE TO RELATED APPLICATION

The present application claims priority under 35 U.S.C. § 119(a) to Korean patent application number 10-2023-0111350 filed on Aug. 24, 2023, in the Korean Intellectual Property Office, the entire contents of which application is incorporated herein by reference.

### BACKGROUND

### 1. Technical Field

The present disclosure generally relates to an electronic device, and more particularly, to a memory device for performing a program operation and an operating method of the memory device.

### 2. Related Art

A memory system is a device which stores data under the control of a host device such as a computer or a smart phone. The memory system may include a memory device for storing data and a memory controller for controlling the memory device. The memory device is classified into a volatile memory device and a nonvolatile memory device.

The nonvolatile memory device is a memory device in which data does not disappear even when the supply of power is interrupted. The nonvolatile memory device may include a Read Only Memory (ROM), a Programmable ROM (PROM), an Electrically Programmable ROM (EPROM), an Electrically Erasable ROM (EEROM), a flash memory, and the like.

The memory device may perform a program operation of storing data in a plurality of memory cells. A threshold voltage of the plurality of memory cells may increase in the program operation. While a threshold voltage of memory cells connected to any one word line increases, a threshold voltage of memory cells connected to another word line may be changed. When a foggy-fine program operation of programming while alternately selecting word lines is performed, a phenomenon in which a threshold voltage of memory cells is changed may be reduced.

### SUMMARY

In accordance with an embodiment of the present disclosure, there is provided a memory device including: a plurality of memory cells;

a peripheral circuit configured to perform a program operation of storing data in the plurality of memory cells; and a program operation control circuit configured to, in the program operation, control the peripheral circuit to perform a foggy program operation of increasing a threshold voltage of the plurality of memory cells to a threshold voltage corresponding to any one state among an erase state and first to sixth foggy program states, and perform a fine program operation of increasing the threshold voltage of the plurality of memory cells to any one state among the erase state and first to fifteenth fine program states.

In accordance with an embodiment of the present disclosure, there is provided a memory device including: a plurality of memory cells; a peripheral circuit configured to perform a program operation of increasing a threshold voltage of the plurality of memory cells; and a program operation control circuit configured to, in the program operation, control the peripheral circuit to perform a foggy program operation of increasing the threshold voltage of the plurality of memory cells to a threshold voltage corresponding to each of first to sixth foggy program states, and perform a fine program operation of increasing a threshold voltage of first memory cells corresponding to the first foggy program state or the second foggy program state among the plurality of memory cells to a threshold voltage corresponding to each of fourth to seventh fine program states or each of eighth to eleventh fine program states among an erase state and first to fifteenth fine program states and increasing a threshold voltage of second memory cells corresponding to each of the third to sixth foggy program states among the plurality of memory cells to a threshold voltage corresponding to each of the twelfth to fifteenth fine program states.

In accordance with an embodiment of the present disclosure, there is provided a method of operating a memory device, the method including: performing a foggy program operation of increasing a threshold voltage of a plurality of memory cells to a threshold voltage corresponding to any one state among an erase state and first to sixth foggy program states; and performing a fine program operation of increasing the threshold voltage of the plurality of memory cells to a threshold voltage corresponding to any one state among the erase state and first to fifteenth fine program states.

### BRIEF DESCRIPTION OF THE DRAWINGS

Embodiments will now be described more fully hereinafter with reference to the accompanying drawings; however, they may be embodied in different forms and should not be construed as limited to the embodiments set forth herein.

In the drawing figures, dimensions may be exaggerated for clarity of illustration. It will be understood that when an element is referred to as being “between” two elements, it can be the only element between the two elements, or one or more intervening elements may also be present. Like reference numerals refer to like elements throughout.

FIG. 1 is a diagram illustrating an embodiment of a memory system including a memory device.

FIG. 2 is a diagram illustrating an embodiment of a program operation of the memory device.

FIG. 3 is a diagram illustrating an embodiment of a threshold voltage distribution according to a foggy program operation and a fine program operation.

FIG. 4 is a diagram illustrating an embodiment of a threshold voltage distribution of memory cells storing at least two-bit data.

FIG. 5 is a diagram illustrating an embodiment of the foggy program operation and the fine program operation according to a program command received from a memory controller.

FIG. 6 is a diagram illustrating an embodiment of the threshold voltage distribution of the memory cells according to the foggy program operation and the fine program operation.

FIG. 7 is a diagram illustrating an embodiment of the threshold voltage distribution of the memory cells storing the at least two bit data.

FIG. 8 is a diagram illustrating an embodiment of the foggy program operation and the fine program operation according to the program command received from the memory controller.

FIGS. 9 and 10 are diagrams illustrating an embodiment of a foggy program operation including a plurality of foggy program loops.

FIG. 11 is a diagram illustrating an embodiment of a fine program operation including a plurality of fine program loops.

FIG. 12 is a diagram illustrating an embodiment of a structure of a three-dimensionally configured memory block.

FIG. 13 is a diagram illustrating an embodiment of an order of a foggy program operation and a fine program operation.

FIG. 14 is a flowchart illustrating an embodiment of a foggy program operation and a fine program operation.

FIG. 15 is a diagram illustrating an embodiment of a structure of a memory device.

FIG. 16 is a diagram illustrating an embodiment of an electronic system including a memory system.

### DETAILED DESCRIPTION

The specific structural or functional description disclosed herein is merely illustrative for the purpose of describing embodiments according to the concept of the present disclosure. The embodiments according to the concept of the present disclosure can be implemented in various forms, and cannot be construed as limited to the embodiments set forth herein.

Various embodiments provide a memory device and an operating method of the memory device, which can improve a threshold voltage distribution of memory cells in a program operation.

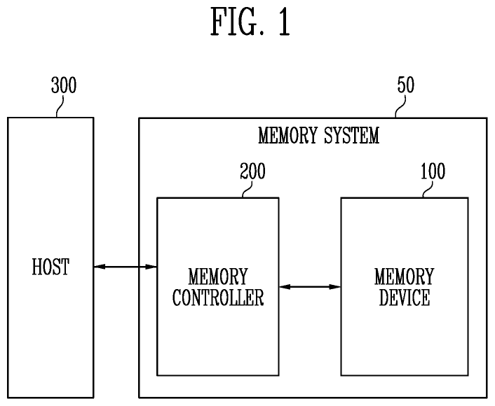

FIG. 1 is a diagram illustrating an embodiment of a memory system including a memory device.

Referring to FIG. 1, the memory system 50 may include a memory device 100 and a memory controller 200. The memory system 50 may be included not only in mobile devices such as a mobile phone, a tablet PC, and a wearable device but also in various electronic devices such as a computer, a server, and an automobile. The memory system 50 may be a device which stores data under the control of a host 300 as an external device.

The memory system 50 may be manufactured as any one of various types of storage devices such as a Solid State Drive (SSD) and a Universal Flash Storage (UFS) according to a host interface as a communication scheme with the host 300. The memory system 50 may be manufactured as any one of various kinds of package types such as a System On Chip (SOC).

The memory device 100 may store data. The memory device 100 may operate under the control of the memory controller 200. In an embodiment, the memory device 100 may be a nonvolatile memory device or a volatile memory device. In this specification, a case where the memory device 100 is a NAND flash memory is assumed and described.

The memory device 100 may receive a command and an address from the memory controller 200, and perform an operation instructed by the command on an area selected by the address. The memory device 100 may a program operation (write operation) of storing data in the area selected by the address, a read operation of reading data from the area selected by the address, or an erase operation of erasing data in the area selected by the address.

The memory controller 200 may control overall operations of the storage system 50.

When power is applied to the memory system 50, the memory controller 200 may execute firmware (FW). In an embodiment, the memory controller 200 may control communication between the host 300 and the memory device 100 by executing the FW. In an embodiment, the memory controller 200 may translate a logical address of the host 300 into a physical address of the memory device 100.

The memory controller 200 may control the memory device 100 to perform a program operation, a read operation, an erase operation, or the like in response to a request of the host 300. The memory controller 200 may provide a command, a physical address or data to the memory device 100 according to a program operation, a read operation or an erase operation.

In an embodiment, the memory controller 200 may autonomously generate a command, an address, and data, regardless of any request from the host 300, and transmit the command, the address, and the data to the memory device 100. For example, the memory controller 200 may provide the memory device 100 with a command, an address, and data, which are used to perform program, read, and erase operations accompanied in performing a background operation such as wear leveling, read reclaim, or garbage collection.

In an embodiment, the memory controller 200 may control at least two memory devices 100. The memory controller 200 may control the memory devices 100 according to an interleaving scheme to improve operational performance. The interleaving scheme may be a scheme for controlling internal operations of at least two memory devices 100 to overlap with each other.

The host 300 may communicate with the memory system 50, using various communication schemes.

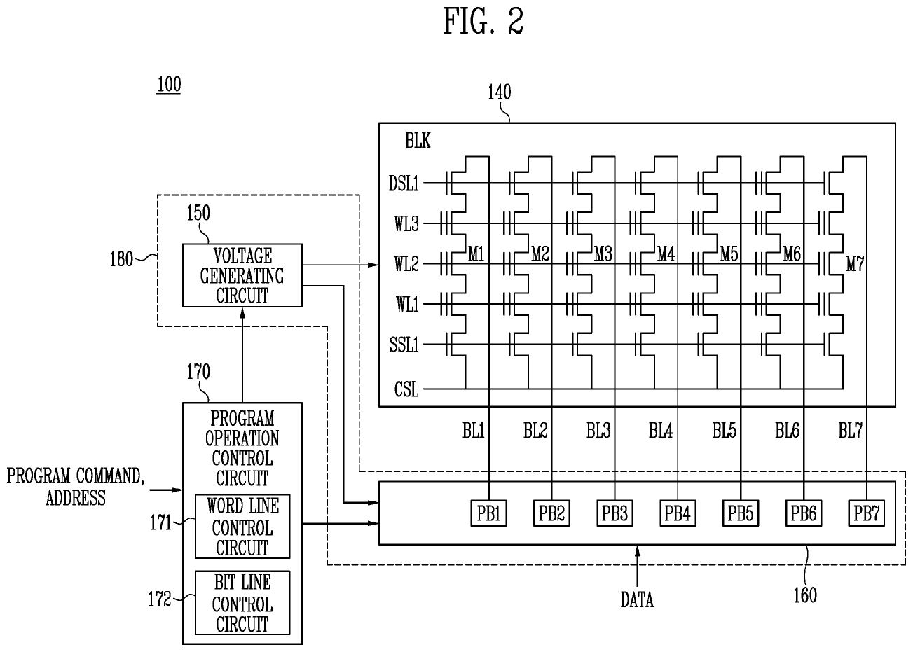

FIG. 2 is a diagram illustrating an embodiment of a program operation of the memory device.

Referring to FIG. 2, the memory device 100 may include a memory block 140, a program operation control circuit 170, and a peripheral circuit 180. The memory block 140 may include a plurality of memory cells connected to a plurality of word lines WL1 to WL3. In an embodiment, first to seventh memory cells M1 to M7 may be commonly connected to a second word line WL2.

The program operation control circuit 170 may include a word line control circuit 171 and a bit line control circuit 172. The peripheral circuit 180 may include a voltage generating circuit 150 and a page buffer group 160. The page buffer group 160 may include first to seventh page buffers PB1 to PB7. The first to seventh page buffers PB1 to PB7 may be respectively connected to first to seventh bit lines BL1 to BL7.

In an embodiment, the program operation control circuit 170 may receive a program command and an address from the memory controller 200. The page buffer group 160 may receive data from the memory controller 200. The program operation control circuit 170 may control the peripheral circuit 180 to perform a program operation on a plurality of memory cells in response to the program command. The program operation may be an operation of storing data on the plurality of memory cells.

In an embodiment, the word line control circuit 171 may control the voltage generating circuit 150 to generate operating voltages used for the program operation. The operating voltages may include a program voltage and a pass voltage, which are applied to the plurality of word lines WL1 to WL3. The operating voltages may include bit line voltages applied to the bit lines BL1 to BL7. The bit line voltages may include a program allow voltage and a program inhibit voltage. The voltage generating circuit 150 may provide the operating voltages to the memory block 140 and the page buffer group 160.

In an embodiment, the word line control circuit 171 may control the voltage generation circuit 150 to apply the program voltage to a selected word line among the plurality of word lines WL1 to WL3 and to apply the pass voltage to unselected word lines among the plurality of word lines WL1 to WL3. In an embodiment, in a program operation, the word line control circuit 171 may control the voltage generating circuit 150 to apply a selected second word line WL2 among the plurality of word lines WL1 to WL3 and to apply the pass voltage to unselected first and third word lines WL1 and WL3. A threshold voltage of the first to seventh memory cells M1 to M7 commonly connected to the second word line WL2 may be increased by the program voltage.

In an embodiment, the bit line control circuit 172 may control the voltage generating circuit 150 and the page buffer group 160 to apply the program allow voltage or the program inhibit voltage to the first to seventh bit lines BL1 to BL7.

In an embodiment, the bit line control circuit 172 may control the voltage generating circuit 150 and the page buffer group 160 to apply the program allow voltage to a bit line connected to a memory cell of which threshold voltage is to be increased. In an embodiment, the program allow voltage may be a ground voltage.

In an embodiment, the bit line control circuit 172 may control the voltage generating circuit 150 and the page buffer group 160 to apply the program inhibit voltage to a bit line connected to a memory cell of which threshold voltage is not to be increased. In an embodiment, the program inhibit voltage may be a power voltage.

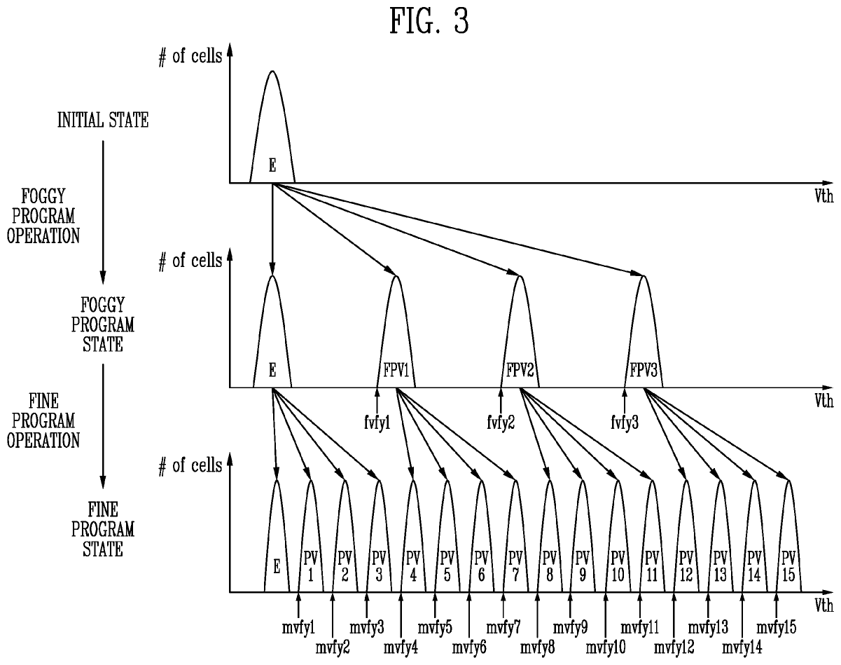

FIG. 3 is a diagram illustrating an embodiment of a threshold voltage distribution according to a foggy program operation and a fine program operation.

In FIG. 3, the horizontal axis of a graph represents threshold voltage Vth of memory cells, and the vertical axis of the graph represents number of memory cells (# of cells).

In FIG. 3, a case where one memory cell is programmed as a Quadruple Level Cell (QLC) storing four-bit data will be described as an example.

Referring to FIG. 3, the memory device 100 may perform a program operation on memory cells. The program operation may include a foggy program operation and a fine program operation. A threshold voltage distribution of the memory cells may be changed from an initial state to a foggy program state according to the foggy program operation. The threshold voltage distribution of the memory cells may be changed from the foggy program state to a fine program state according to the fine program operation.

The initial state is a state in which the program operation is not performed, and the threshold voltage distribution of the memory cells may be an erase state E.

The foggy program state may be a program state of memory cells on which the foggy program state is performed. The foggy program state may include the erase state E and first to third foggy program states FPV1 to FPV3. The foggy program operation may be an operation in which a threshold voltage of the memory cells has a threshold voltage corresponding to each of the erase state E and the first to third foggy program states FPV1 to FPV3. The foggy program operation may be an operation using first to third foggy verify voltages fvfy1 to fvfy3 respectively corresponding to the first to third foggy program states FPV1 to FPV3.

The fine program state may be a program state of memory cells on which the fine program operation is performed. The fine program state may include the erase state E and first to fifteen fine program states PV1 to PV15. The fine program operation may be an operation in which a threshold voltage of the memory cells has a threshold voltage corresponding to each of the erase state E and the first to fifteen fine program states PV1 to PV15. The fine program operation may be an operation using first to fifteenth fine verify voltages mvfy1 to mvfy15 respectively corresponding to the first to fifteen fine program states PV1 to PV15.

Each of the memory cells may have, as a target program state, any one of the erase state E and the first to fifteenth program states PV1 to PV15, which are included in the fine program state. The target program state may be determined according to data to be stored in each memory cell.

Specifically, first memory cells having, as a target program state, as each of the erase state E and the first to third fine program states PV1 to PV3 among the memory cells may have a threshold voltage corresponding to the erase state E according to the foggy program operation. Also, the first memory cells may have a threshold voltage corresponding to each of the erase state E and the first to third fine program states PV1 to PV3 according to the fine program operation.

Second memory cells having, as a target program state, each of the fourth to seventh fine program states PV4 to PV7 among the memory cells may have a threshold voltage correspond to the first foggy program state FPV1 according to the foggy program operation. Also, the second memory cells may have a threshold voltage corresponding to each of the fourth to seventh fine program states PV4 to PV7 according to the fine program operation.

Third memory cells having, as a target program state, each of the eighth to eleventh program states PV8 to PV11 among the memory cells may have a threshold voltage corresponding to the second foggy program state FPV2 according to the foggy program operation. Also, the third memory cells may have a threshold voltage corresponding to each of the eighth to eleventh program states PV8 to PV11 according to the fine program operation.

Fourth memory cells having, as a target program state, each of the twelfth to fifteenth fine program state PV12 to PV15 among the memory cells may have a threshold voltage corresponding to the third foggy program state FPV3 according to the foggy program operation. Also, the fourth memory cells may have a threshold voltage corresponding to each of the twelfth to fifteenth fine program state PV12 to PV15 according to the fine program operation.

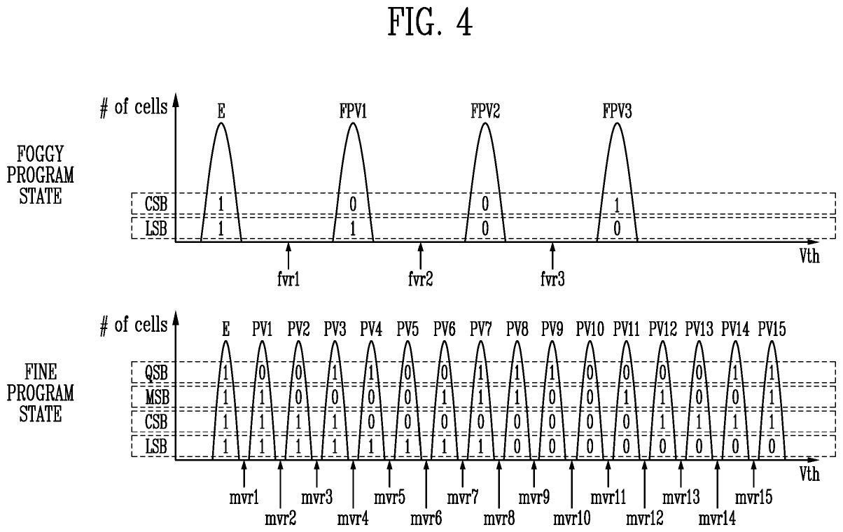

FIG. 4 is a diagram illustrating an embodiment of a threshold voltage distribution of memory cells storing at least two-bit data.

In FIG. 4, the horizontal axis of a graph represents threshold voltage Vth of memory cells, and the vertical axis of the graph represents number of memory cells (#of cells).

Referring to FIG. 4, the foggy program state may be a program state of memory cells on which the foggy program operation is performed. The memory cells on which the foggy program operation is performed may have a threshold voltage corresponding to each of the ease state E and the first to third foggy program states FPV1 to FPV3.

In an embodiment, two-bit data may be stored in one memory cell according to the foggy program operation. For example, the data stored in the one memory cell may be least significant bit (LSB) data and center significant bit (CSB) data.

In an embodiment, data of “11” may be stored in memory cells having, as a target program state, each of the ease state E and the first to third fine program states PV1 to PV3 according to the foggy program operation. Data of “10” may be stored in memory cells having, as a target program state, each of the fourth to seventh fine program states PV4 to PV7 according to the foggy program operation. Data of “00” may be stored in memory cells having, as a target program state, each of the eighth to eleventh fine program states PV8 to PV11 according to the foggy program operation. Data of “01” may be stored in memory cells having, as a target program state, each of the twelfth to fifteenth fine program states PV12 to PV15 according to the foggy program operation.

First to third foggy read voltages fvr1 to fvr3 may be read voltages for distinguishing the erase state E and the first to third foggy program states FPV1 to FPV3 from each other in the foggy program state. In an embodiment, the second foggy read voltage fvr2 may be a voltage for reading LSB data. The first foggy read voltage fvr1 and the third foggy read voltage fvr3 may be voltages for reading CSB data. The memory device 100 may perform the foggy program operation and then read LSB data and CSB data, which are stored in memory cells, by using the first to third foggy read voltages fvr1 to fvr3.

In an embodiment, four-bit data may be stored in one memory cell according to a fine program operation. For example, LSB data, CSB data, most significant bit (MSB) data, and QSB data may be stored in the one memory cell.

First to fifteenth fine read voltages mvr1 to mvr15 may be read voltage for distinguishing the erase state E and the first to fifteenth fine program states PV1 to PV15 from each other in the fine program state. In an embodiment, the eighth fine read voltage mvr8 may be a voltage for reading LSB data. The fourth fine read voltage mvr4 and the twelfth fine read voltage mvr12 may be voltages for reading CSB data. The second fine read voltage mvr2, the sixth fine read voltage mvr6, the ninth fine read voltage mvr9, the eleventh fine read voltage mvr11, the thirteenth fine read voltage mvr13, and the fifteenth fine read voltage mvr15 may be voltages for reading MSB data. The first fine read voltage mvr1, the third fine read voltage mvr3, the fifth fine read voltage mvr5, the seventh fine read voltage mvr7, the tenth fine read voltage mvr10, and the fourteenth fine read voltage mvr14 may be voltages for reading QSB data.

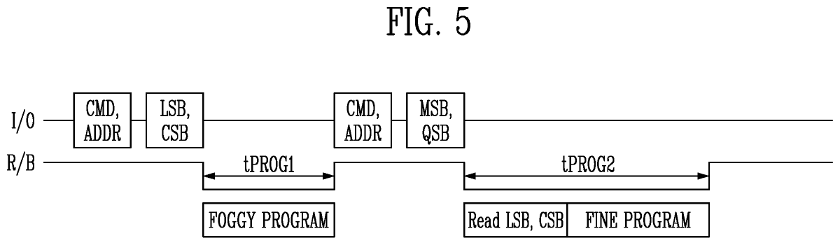

FIG. 5 is a diagram illustrating an embodiment of the foggy program operation and the fine program operation according to a program command received from the memory controller.

Referring to FIG. 5, an input/output line I/O and a ready/busy line R/B are illustrated. The memory device 100 may receive a program command CMD, an address ADDR, and data from the memory controller 200 through the input/output line I/O. The memory device 100 may output a status signal to the memory controller 200 through the ready/busy line R/B. For example, the memory device 100 may output a busy status signal to the memory controller 200 while an internal operation is performed. The busy status signal may be logic low. The memory device 100 may output a ready status signal to the memory controller 200 while any operation is not performed. The read status signal may be logic high.

In an embodiment, the memory device 100 may receive a program command CMD, an address ADDR, LSB data, and CSB data from the memory controller 200. The memory device 100 may perform a foggy program operation on an area selected by the address ADDR, using the LSB data and CSB data. The time required to perform the foggy program operation may be a first program time tPROG1. The memory device 100 may output the busy status signal.

After that, the memory device 100 may receive a program command CMD, an address ADDR, MSB data and QSB data from the memory controller 200. The memory device 100 may read LSB data and CSB data from memory cells on which the foggy program operation is performed. The memory device 100 may perform a fine program operation by using the LSB data and the CSB data, which are read from the memory cells, and the MSB data and the QSB data, which are received from the memory controller 200. A time required to perform the fine program operation may be a second program time tPROG2. The memory device 100 may output the busy status signal.

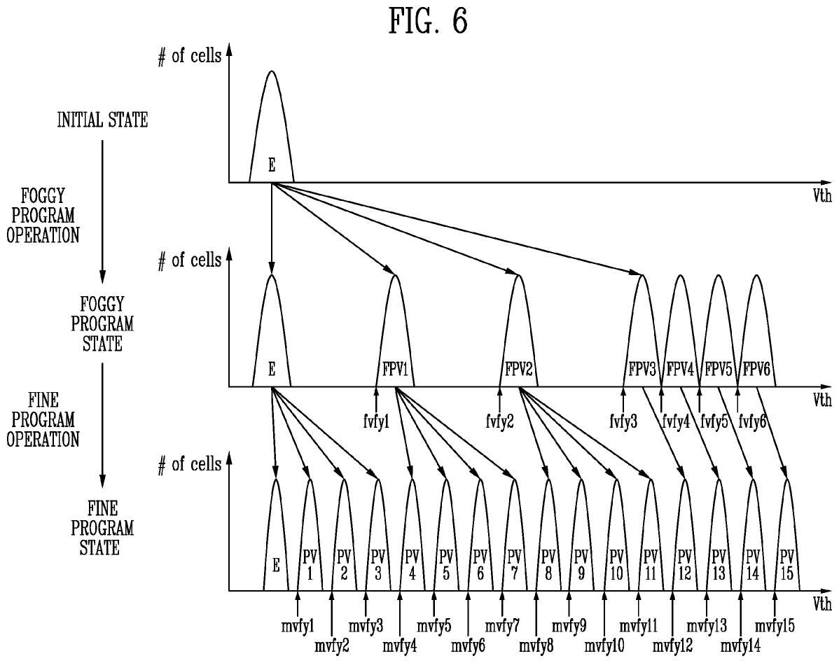

FIG. 6 is a diagram illustrating an embodiment of the threshold voltage distribution of the memory cells according to the foggy program operation and the fine program operation.

In FIG. 6, the horizontal axis of a graph represents threshold voltage Vth of memory cells, and the vertical axis of the graph represents number of memory cells (#of cells).

Referring to FIG. 6, the memory device may perform a program operation including a foggy program operation and a fine program operation. A threshold voltage distribution of memory cells may be changed from an initial state to a foggy program state according to the foggy program operation.

The foggy program state may be a program state of memory cells on which the foggy program operation is performed. The foggy program state may include an erase state E and first to sixth foggy program states FPV1 to FPV6. The foggy program operation may be an operation in which a threshold voltage of the memory cells has a threshold voltage corresponding to each of the erase state E and the first to sixth foggy program states FPV1 to FPV6. The foggy program operation may be an operation using first to sixth foggy verify voltages fvfy1 to fvfy6 respectively corresponding to the first to sixth foggy program states FPV1 to FPV6. The memory device 100 may identify whether a threshold voltage of memory cells have increased to a threshold voltage corresponding to each of the first to sixth foggy program states FPV1 to FPV6 by using the first to sixth foggy verify voltages fvfy1 to fvfy6. In an embodiment, the memory device 100 may perform the fine program operation on the memory cells when a foggy verify operation using the first to sixth foggy verify voltages fvfy1 to fvfy6 passes in the foggy program operation.

The memory device 100 may perform the fine program operation on the memory cells after the threshold voltage of the memory cells increase to a threshold voltage corresponding to each of the erase state E and the first to sixth foggy program states FPV1 to FPV6 according to the foggy program operation.

A fine program state may be a program state of memory cells on which the fine program operation is performed. The fine program state may include the erase state E and first to fifteenth fine program states PV1 to PV15. The fine program operation may be an operation in which a threshold voltage of the memory cells has a threshold voltage corresponding to each of the erase state E and the first to fifteenth fine program states PV1 to PV15. The fine program operation may be an operation using first to fifteenth fine verify voltages mvfy1 to mvfy15 respectively corresponding to the first to fifteenth fine program states PV1 to PV15. The memory device 100 may identify whether a threshold voltage of memory cells have increased to a threshold voltage corresponding to each of the first to fifteenth fine program states PV1 to PV15 by using the first to fifteenth fine verify voltages mvfy1 to mvfy15. In an embodiment, the program operation may be completed when a fine verify operation using the first to fifteenth fine verify voltages mvfy1 to mvfy15 passes.

Specifically, first memory cells having, as a target program state, each of the erase state E and the first to third fine program states PV1 to PV3 among the memory cells may have a threshold voltage corresponding to the erase state E according to the foggy program operation. Also, the first memory cells may have a threshold voltage corresponding to each of the erase state E and the first to third fine program states PV1 to PV3 according to the fine program operation.

Second memory cells having, as a target program state, each of the fourth to seventh fine program states PV4 to PV7 among the memory cells may have a threshold voltage corresponding to the first foggy program state FPV1 according to the foggy program operation. Also, the second memory cells may have a threshold voltage corresponding to each of the fourth to seventh fine program states PV4 to PV7 according to the fine program operation.

Third memory cells having, as a target program state, each of the eighth to eleventh fine program states PV8 to PV11 among the memory cells may have a threshold voltage corresponding to the second foggy program state FPV2 according to the foggy program operation. Also, the third memory cells may have a threshold voltage corresponding to each of the eighth to eleventh fine program states PV8 to PV11 according to the fine program operation.

Fourth memory cells having the twelfth fine program state PV12 as a target program state among the memory cells may have a threshold voltage corresponding to the third foggy program state FPV3 according to the foggy program operation. Also, the fourth memory cells may have a threshold voltage corresponding to the twelfth fine program state PV12 according to the fine program operation.

Fifth memory cells having the thirteenth fine program state PV13 as a target program state among the memory cells may have a threshold voltage corresponding to the fourth foggy program state FPV4 according to the foggy program operation. Also, the fifth memory cells may have a threshold voltage corresponding to the thirteenth fine program state PV12 according to the fine program operation.

Sixth memory cells having the fourteenth fine program state PV14 as a target program state among the memory cells may have a threshold voltage corresponding to the fifth foggy program state FPV5 according to the foggy program operation. Also, the sixth memory cells may have a threshold voltage corresponding to the fourteenth fine program state PV14 according to the fine program operation.

Seventh memory cells having the fifteenth fine program state PV15 as a target program state among the memory cells may have a threshold voltage corresponding to the sixth foggy program state FPV6 according to the foggy program operation. Also, the seventh memory cells may have a threshold voltage corresponding to the fifteenth fine program state PV15 according to the fine program operation.

In an embodiment, memory cells having a threshold voltage corresponding to the erase state, the first foggy program state, or the second foggy program state according to the foggy program operation may have a threshold voltage corresponding to each of four fine program states according to the fine program operation.

In an embodiment, memory cells having a threshold voltage corresponding to each of the third to sixth foggy program states as four foggy program states according to the foggy program operation may have a threshold voltage corresponding to each of four fine program states according to the fine program operation.

In an embodiment, in the program operation on memory cells having, as a target program state, each of the twelfth to fifteenth fine program states PV12 to PV15, the memory device 100 may perform the foggy program operation of increasing the threshold voltage of the memory cells to a threshold voltage corresponding to each of the third to sixth foggy program states FPV3 to FPV6, and then perform the fine program operation of increasing the threshold voltage of the memory cells to a threshold voltage corresponding to each of the twelfth to fifteenth fine program states PV12 to PV15. In the foggy program operation, in an embodiment, the memory device 100 increases the threshold voltage of the memory cells having, as the target program state, each of the twelfth to fifteenth fine program state PV12 to PV15 to have different foggy program states, so that a phenomenon can be reduced or prevented, in which a threshold voltage of memory cells is changed by disturbance between adjacent word lines in the foggy program operation and the fine program operation.

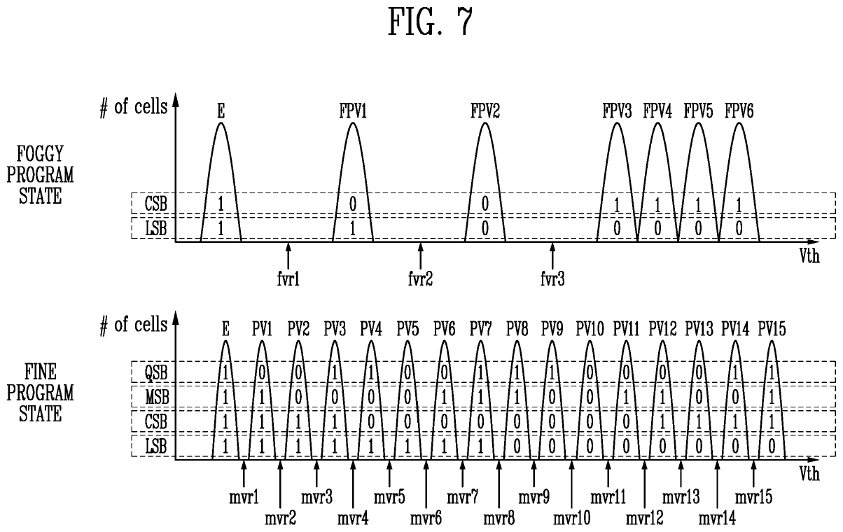

FIG. 7 is a diagram illustrating an embodiment of the threshold voltage distribution of the memory cells storing the at least two bit data.

In FIG. 7, the horizontal axis of a graph represents threshold voltage Vth of memory cells, and the vertical axis of the graph represents number of memory cells (#of cells).

Referring to FIG. 7, the foggy program state may be a program state of memory cells on which the foggy program operation is performed. The memory cells on which the foggy program operation is performed may have a threshold voltage corresponding to each of the ease state E and the first to sixth foggy program states FPV1 to FPV6.

In an embodiment, two-bit data may be stored in one memory cell according to the foggy program operation. For example, the data stored in the one memory cell may be LSB data and CSB data. In an embodiment, the same LSB data and the same CSB data may be stored in memory cells having a threshold voltage corresponding to each of the third to sixth foggy program states. In an embodiment, data of “01” may be stored in the memory cells having the threshold voltage corresponding to each of the third to sixth foggy program states.

First to third foggy read voltages fvr1 to fvr3 may be read voltages for distinguishing the erase state E and the first to third foggy program states FPV1 to FPV3 from each other in the foggy program state. In an embodiment, the second foggy read voltage fvr2 may be a voltage for reading LSB data. The first foggy read voltage fvr1 and the third foggy read voltage fvr3 may be voltages for reading CSB data. The memory device 100 may perform the foggy program operation and then read LSB data and CSB data, which are stored in memory cells, by using the first to third foggy read voltages fvr1 to fvr3.

In an embodiment, apart from FIG. 3, because data stored in memory cells having a threshold voltage corresponding to each of the third to sixth foggy program states FPV3 to FPV6 are the same even when a threshold voltage distribution corresponding to the fourth to sixth foggy program states FPV4 to FPV6 is additionally formed in the foggy program operation, the memory device 100 may read data stored in the memory cells having the threshold voltage corresponding to each of the third to sixth foggy program states FPV3 to FPV6 by using only the first to third foggy read voltages fvr1 to fvr3 without any additional read voltage.

In an embodiment, four-bit data may be stored in one memory cell according to a fine program operation. For example, LSB data, CSB data, MSB data, and QSB data may be stored in the one memory cell.

First to fifteenth fine read voltages mvr1 to mvr15 may be read voltage for distinguishing the erase state E and the first to fifteenth fine program states PV1 to PV15 from each other in the fine program state. The memory device 100 may perform the fine program operation and then read data stored in memory cells by using the first to fifteenth fine read voltages mvr1 to mvr15.

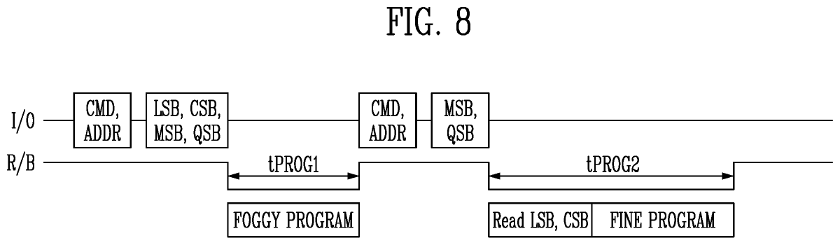

FIG. 8 is a diagram illustrating an embodiment of the foggy program operation and the fine program operation according to the program command received from the memory controller.

Referring to FIG. 8, the memory device 100 may receive a program command CMD, an address ADDR, LSB data, CSB data, MSB data, and QSB data from the memory controller 200. The memory device 100 may perform a foggy program operation on an area selected by the address ADDR, using the LSB data, CSB data, the MSB data, and the QSB data. A threshold voltage of memory cells may have a threshold voltage corresponding to each of the first to sixth foggy program states FPV1 to FPV6 according to the LSB data, CSB data, the MSB data, and the QSB data, which are received from the memory controller 200.

After that, the memory device 100 may receive a program command CMD, an address ADDR, MSB data, and QSB data from the memory controller 200. The memory device 100 may read LSB data and CSB data from memory cells on which the foggy program operation is performed. The memory device 100 may perform a fine program operation by using the LSB data and the CSB data, which are read from the memory cells, and the MSB data and the QSB data, which are received from the memory controller 200. A threshold voltage of the memory cells may have a threshold voltage corresponding to each of the erase state E and the first to fifteenth fine program states PV1 to PV15 according to the LSB data and the CSB data, which are read from the memory cells, and the MSB data and the QSB data, which are received from the memory controller 200.

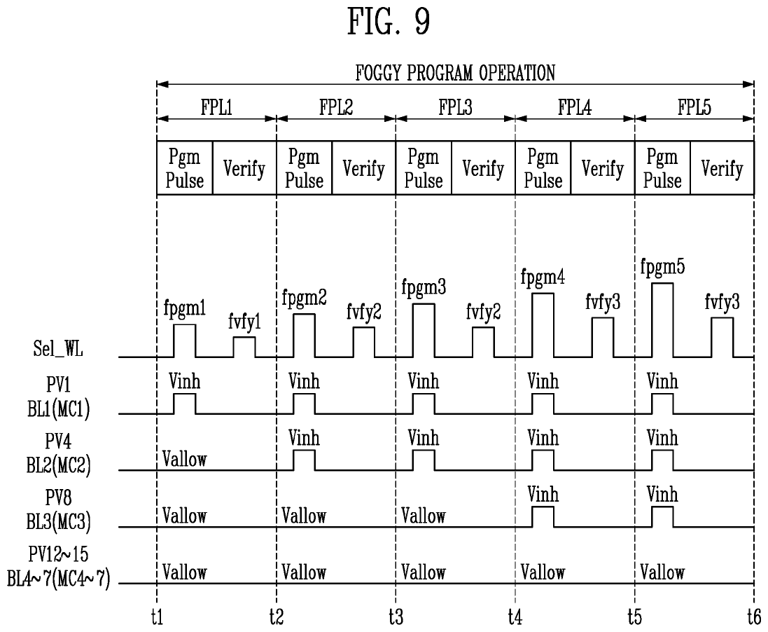

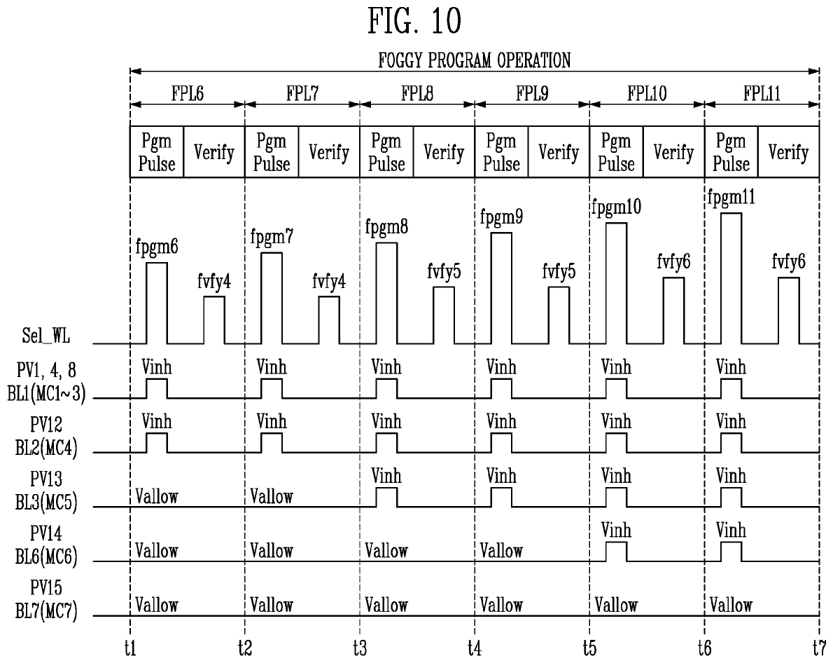

FIGS. 9 and 10 are diagrams illustrating an embodiment of a foggy program operation including a plurality of foggy program loops. As used herein, the tilde “˜” indicates a range of components. For example, “PV12˜PV15” indicates the fine program states PV12, PV13, PV14, and PV15 shown in FIGS. 6 and 9.

FIGS. 9 and 10 will be described with reference to FIGS. 2 and 6. Referring to FIGS. 9 and 10, the memory device 100 may perform a foggy program operation. The foggy program operation may include a plurality of foggy program loops. In FIGS. 9 and 10, a case where the foggy program operation including eleven foggy program loops is performed will be described as an example.

In an embodiment, each of first to eleventh foggy program loops PPL1 to PPL11 may include a foggy program voltage apply operation Pgm Pulse and a foggy verify operation Verify. The foggy program voltage apply operation Pgm Pulse may be an operation of applying a foggy program voltage fpgm to a selected word line Sel_WL and applying a program allow voltage Vallow or a program inhibit voltage Vinh to bit lines connected to selected memory cells connected to the selected word line Sel_WL. The foggy verify operation Verify may be an operation of identifying whether a threshold voltage of the selected memory cells exceeds a foggy verify voltage fvfy by applying the foggy verify voltage fvfy to the selected word line WL.

First, referring to FIG. 9, the memory device 100 may perform a foggy program operation on first to seventh memory cells MC1 to MC7 connected to a selected second word line among a plurality of word lines.

In an embodiment, the first memory cell MC1 may have the first fine program state PV1 as a target program state. The first memory cell MC1 may have a threshold voltage corresponding to the erase state E in the foggy program operation. A foggy program operation on memory cells having, as a target program state, each of the second and third fine program states PV2 and PV3 may be performed identically to the foggy program operation on the first memory cells MC1.

The second memory cell MC2 may have the fourth fine program state PV4 as a target program state. The second memory cell MC2 may have a threshold voltage increasing to a threshold voltage corresponding to the first foggy program state FPV1 in the foggy program operation. A foggy program operation on memory cells having, as a target program state, each of the fifth to seventh fine program states PV5 to PV7 may be performed identically to the foggy program operation on the second memory cell MC2.

The third memory cell MC3 may have the eighth fine program state PV8 as a target program state. The third memory cell MC3 may have a threshold voltage increasing to a threshold voltage corresponding to the second foggy program state FPV2 in the foggy program operation. A foggy program operation on memory cells having, as a target program state, each of the ninth to eleventh fine program states PV9 to PV11 may be performed identically to the foggy program operation on the third memory cell MC3.

The fourth memory cell MC4 may have the twelfth fine program state PV12 as a target program state. The fourth memory cell MC4 may have a threshold voltage increasing to a threshold voltage corresponding to the third foggy program state FPV3 in the foggy program operation.

The fifth memory cell MC5 may have the thirteenth fine program state PV13 as a target program state. The fifth memory cell MC5 may have a threshold voltage increasing to a threshold voltage corresponding to the fourth foggy program state FPV4 in the foggy program operation.

The sixth memory cell MC6 may have the fourteenth fine program state PV14 as a target program state. The sixth memory cell MC6 may have a threshold voltage increasing to a threshold voltage corresponding to the fifth foggy program state FPV5 in the foggy program operation.

The seventh memory cell MC7 may have the fifteenth fine program state PV15 as a target program state. The seventh memory cell MC7 may have a threshold voltage increasing to a threshold voltage corresponding to the sixth foggy program state FPV6 in the foggy program operation.

In an embodiment, in the first foggy program loop FPL1, the memory device 100 may apply a first foggy program voltage fpgm1 to the selected word line Sel_WL. The first memory cell MC1 is to have a threshold voltage corresponding to the erase state E in the foggy program operation, and therefore, the threshold voltage of the first memory cell MC1 may be not to increase. In the first foggy program loop FPL1, the memory device 100 may apply the program inhibit voltage Vinh to a first bit line BL1 connected to the first memory cell MC1.

In an embodiment, in the first foggy program loop FPL1, the memory device 100 may apply the program allow voltage Vallow to second to seventh bit lines BL2 to BL7 connected to the second to seventh memory cells MC2 to MC7.

In the first foggy program loop FPL1, the memory device 100 may apply a first foggy verify voltage fvfy1 to the selected word line Sel_WL. The memory device 100 may identify whether a threshold voltage of memory cells has increased to the threshold voltage corresponding to the first foggy program state FPV1 by using the first foggy verify voltage fvfy1. Because a threshold voltage of the second memory cell MC2 is to increase to the threshold voltage corresponding to the first foggy program state FPV1 in the foggy program operation, the foggy verify operation may pass when the threshold voltage of the second memory cell MC2 exceeds the first foggy verify voltage fvfy1. Because the threshold voltage of the second memory cell MC2 is to no longer increase when the threshold voltage of the second memory cell MC2 exceeds the first foggy verify voltage fvfy1, the program inhibit voltage Vinh may be applied to the second bit line BL2 connected to the second memory cell MC2 in a next foggy program loop.

In the second foggy program loop FPL2, the memory device 100 may apply a second foggy program voltage fpgm2 higher by a step voltage than the first foggy program voltage fpgm1 to the selected word line Sel_WL. In the second foggy program loop FPL2, because the threshold voltage of each of the first and second memory cells MC1 and MC2 is not to increase, the memory device 100 may apply the program inhibit voltage Vinh to the first and second bit lines BL1 and BL2 connected to the first and second memory cells MC1 to MC2.

In the second foggy program loop FPL2, the memory device 100 may apply the program allow voltage Vallow to the third to seventh bit lines BL3 to BL7 connected to the third to seventh memory cells MC3 to MC7, each of threshold voltage is to increase.

In the second foggy program loop FPL2, the memory device 100 may apply a second foggy verify voltage fvfy2 to the selected word line Sel_WL. The memory device 100 may identify whether a threshold voltage of memory cells has increased to the threshold voltage corresponding to the second foggy program state FPV2 by using the second foggy verify voltage fvfy2. Because a threshold voltage of the third memory cell MC3 is to increase the threshold voltage corresponding to the second foggy program state FPV2 in the foggy program operation, the threshold voltage of the third memory cells MC3 may be to exceed the second foggy verify voltage fvfy2. However, in the second foggy program loop FPL2, the foggy verify operation may fail when the threshold voltage of the third memory cell MC3 is the second foggy verify voltage fvfy2 or lower.

In the third foggy program loop FPL3, the memory device 100 may apply a third foggy program voltage fpgm3 higher by the step voltage than the second foggy program voltage fpgm2. In the third foggy program loop FPL3, the memory device 100 may apply the program inhibit voltage Vinh to the first and second bit lines BL1 and BL2 connected to the first and second memory cells MC1 and MC2. In the third foggy program loop FPL3, the memory device 100 may apply the program allow voltage Vallow to the third to seventh bit lines BL3 to BL7 connected to the third to seventh memory cells MC3 to MC7.

In the third foggy program loop FPL3, the memory device 100 may apply the second foggy verify voltage fvfy2 to the selected word line Sel_WL. In the third foggy program loop FPL3, the foggy verify operation may pass when the threshold voltage of the third memory cell MC3 exceeds the second foggy verify voltage fvfy2.

In the fourth foggy program loop FPL4, the memory device 100 may apply a fourth foggy program voltage fpgm4 higher by the step voltage than the third foggy program voltage fpgm3. In the fourth foggy program loop FPL4, the memory device 100 may apply the program inhibit voltage Vinh to the first to third bit lines BL1 to BL3 connected to the first to third memory cells MC1 to MC3, each of which threshold voltage is not to increase. In the fourth foggy program loop FPL4, the memory device 100 may apply the program allow voltage Vallow to the fourth to seventh bit lines BL4 to BL7 connected to the fourth to seventh memory cells MC4 to MC7, each of which threshold voltage is to increase.

In the fourth foggy program loop FPL4, the memory device 100 may apply a third foggy verify voltage fvfy3 to the selected word line Sel_WL. The memory device 100 may identify whether a threshold voltage of memory cells has increased to the threshold voltage corresponding to the third foggy program state FPV3 by using the third foggy verify voltage fvfy3. Because a threshold voltage of the fourth memory cell MC4 is to increase the threshold voltage corresponding to the third foggy program state FPV3 in the foggy program operation, the threshold voltage of the fourth memory cell MC4 may be to exceed the third foggy verify voltage fvfy3. However, in the fourth foggy program loop FPL4, the foggy verify operation may fail when the threshold voltage of the fourth memory cell MC4 is the third foggy verify voltage fvfy3 or lower.

In the fifth foggy program loop FPL5, the memory device 100 may apply a fifth foggy program voltage fpgm5 higher by the step voltage than the fourth foggy program voltage fpgm4. In the fifth foggy program loop FPL5, the memory device 100 may apply the program inhibit voltage Vinh to the first to third bit lines BL1 to BL3 connected to the first to third memory cells MC1 to MC3. In the fifth foggy program loop FPL5, the memory device 100 may apply the program allow voltage Vallow to the fourth to seventh bit lines BL4 to BL7 connected to the fourth to seventh memory cells MC4 to MC7.

In the fifth foggy program loop FPL5, the memory device 100 may apply the third foggy verify voltage fvfy3 to the selected word line Sel_WL. In the fifth foggy program loop FPL5, the foggy verify operation may pass when the threshold voltage of the fourth memory cell MC4 exceeds the third foggy verify voltage fvfy3.

Next, referring to FIG. 10, in the sixth foggy program loop FPL6, the memory device 100 may apply a sixth foggy program voltage fpgm6 higher by the step voltage than the fifth foggy program voltage fpgm5. In the sixth foggy program loop FPL6, the memory device 100 may apply the program inhibit voltage Vinh to the first to fourth bit lines BL1 to BL4 connected to the first to fourth memory cells MC1 to MC4. In the sixth foggy program loop FPL6, the memory device 100 may apply the program allow voltage Vallow to the fifth to seventh bit lines BL5 to BL7 connected to the fifth to seventh memory cells MC5 to MC7.

In the sixth foggy program loop FPL6, the memory device 100 may apply a fourth foggy verify voltage fvfy4 to the selected word line Sel_WL. The memory device 100 may identify whether a threshold voltage of memory cells has increased to the threshold voltage corresponding to the fourth foggy program state FPV4 by using the fourth foggy verify voltage fvfy4. Because a threshold voltage of the fifth memory cell MC5 is to increase to the threshold voltage corresponding to the fourth foggy program state FPV4 in the foggy program operation, the threshold voltage of the fifth memory cell MC5 may be to exceed the fourth foggy verify voltage fvfy4. However, in the sixth foggy program loop FPL6, the foggy program verify operation may fail when the threshold voltage of the fifth memory cell MC5 is the fourth foggy verify voltage fvfy4 or lower.

In the seventh foggy program loop FPL7, the memory device 100 may apply a seventh foggy program voltage fpgm7 higher by the step voltage than the sixth foggy program voltage fpgm6. In the seventh foggy program loop FPL7, the memory device 100 may apply the program inhibit voltage Vinh to the first to fourth bit lines BL1 to BL4 connected to the first to fourth memory cells MC1 to MC4. In the seventh foggy program loop FPL7, the memory device 100 may apply the program allow voltage Vallow to the fifth to seventh bit lines BL5 to BL7 connected to the fifth to seventh memory cells MC5 to MC7.

In the seventh foggy program loop FPL7, the memory device 100 may apply the fourth foggy verify voltage fvfy4 to the selected word line Sel_WL. In the seventh foggy program loop FPL7, the foggy verify operation may pass when the threshold voltage of the fifth memory cell MC5 exceeds the fourth foggy verify voltage fvfy4.

In the eighth foggy program loop FPL8, the memory device 100 may apply an eighth foggy program voltage fpgm8 higher by the step voltage than the seventh foggy program voltage fpgm7. In the eight foggy program loop FPL8, the memory device 100 may apply the program inhibit voltage Vinh to the first to fifth bit lines BL1 to BL5 connected to the first to fifth memory cells MC1 to MC5. In the eight foggy program loop FPL8, the memory device 100 may apply the program allow voltage Vallow to the sixth and seventh bit lines BL6 and BL7 connected to the sixth and seventh memory cells MC6 and MC7.

In the eighth foggy program loop FPL8, the memory device 100 may apply a fifth foggy verify voltage fvfy5 to the selected word line Sel_WL. The memory device 100 may identify whether a threshold voltage of memory cells has increased to the threshold voltage corresponding to the fifth foggy program state FPV5 by using the fifth foggy verify voltage fvfy5. Because a threshold voltage of the sixth memory cell MC6 is to increase to the threshold voltage corresponding to the fifth foggy program state FPV5 in the foggy program operation, the threshold voltage of the sixth memory cell MC6 may be to exceed the fifth foggy verify voltage fvfy5. However, in the eighth foggy program loop FPL8, the foggy verify operation may fail when the threshold voltage of the sixth memory cell MC6 is the fifth foggy verify voltage fvfy5 or lower.

In the ninth foggy program loop FPL9, the memory device 100 may apply a ninth foggy program voltage fpgm9 higher by the step voltage than the eighth foggy program voltage fpgm8. In the ninth foggy program loop FPL9, the memory device 100 may apply the program inhibit voltage Vinh to the first to fifth bit lines BL1 to BL5 connected to the first to fifth memory cells MC1 to MC5. In the ninth foggy program loop FPL9, the memory device 100 may apply the program allow voltage Vallow to the sixth and seventh bit lines BL6 and BL7 connected to the sixth and seventh memory cells MC6 and MC7.

In the ninth foggy program loop FPL9, the memory device 100 apply the fifth foggy verify voltage fvfy5 to the selected word line Sel_WL. In the ninth foggy program loop FPL9, the foggy verify operation may pass when the threshold voltage of the sixth memory cell MC6 exceeds the fifth foggy verify voltage fvf5.

In the tenth foggy program loop FPL10, the memory device 100 may apply a tenth foggy program voltage fpgm10 higher by the step voltage than the ninth foggy program voltage fpgm9. In the tenth foggy program loop FPL10, the memory device 100 may apply the program inhibit voltage Vinh to the first to sixth bit lines BL1 to BL6 connected to the first to sixth memory cells MC1 to MC6. In the tenth foggy program loop FPL10, the memory device 100 may apply the program allow voltage Vallow to the seventh bit line BL7 connected to the seventh memory cells MC7.

In the tenth foggy program loop FPL10, the memory device 100 may apply a sixth foggy verify voltage fvfy6 to the selected word line Sel_WL. The memory device 100 may identify whether a threshold voltage of memory cells has increased to the threshold voltage corresponding to the sixth foggy program state FPV6 by using the sixth foggy verify voltage fvfy6. Because a threshold voltage of the seventh memory cell MC7 is to increase to the threshold voltage corresponding to the sixth foggy program state FPV6 in the foggy program operation, the threshold voltage of the seventh memory cell MC7 may be to exceed the sixth foggy verify voltage fvfy6. However, in the tenth foggy program loop FPL10, the foggy verify operation may fail when the threshold voltage of the seventh memory cell MC7 is the sixth foggy verify voltage fvfy6 or lower.

In the eleventh foggy program loop FPL11, the memory device 100 may apply an eleventh foggy program voltage fpgm11 higher by the step voltage than the tenth foggy program voltage fpgm10. In the eleventh foggy program loop FPL11, the memory device 100 may apply the program inhibit voltage Vinh to the first to sixth bit lines BL1 to BL6 connected to the first to sixth memory cells MC1 to MC6. In the eleventh foggy program loop FPL11, the memory device 100 may apply the program allow voltage Vallow to the seventh bit line BL7 connected to the seventh memory cell MC7.

In the eleventh foggy program loop FPL11, the memory device 100 may apply the sixth foggy verify voltage fvfy6 to the selected line Sel_WL. In the eleventh foggy program loop FPL11, the foggy verify operation may pass when the threshold voltage of the seventh memory cell MC7 exceeds the sixth foggy verify voltage fvfy6.

In an embodiment, the foggy program operation may be completed when the threshold voltage of each of the first to seventh memory cells MC1 to MC7 has the threshold voltage corresponding to each of the erase state E and the first to sixth foggy program states FPV1 to FPV6. In an embodiment, when the foggy verify operation using the first to sixth foggy verify voltages fvfy1 to fvfy6 passes, the foggy program operation may be completed. The memory device 100 may perform a fine program operation on the first to seventh memory cells MC1 to MC7 after the foggy program operation on the first to seventh memory cells MC1 to MC7 is completed.

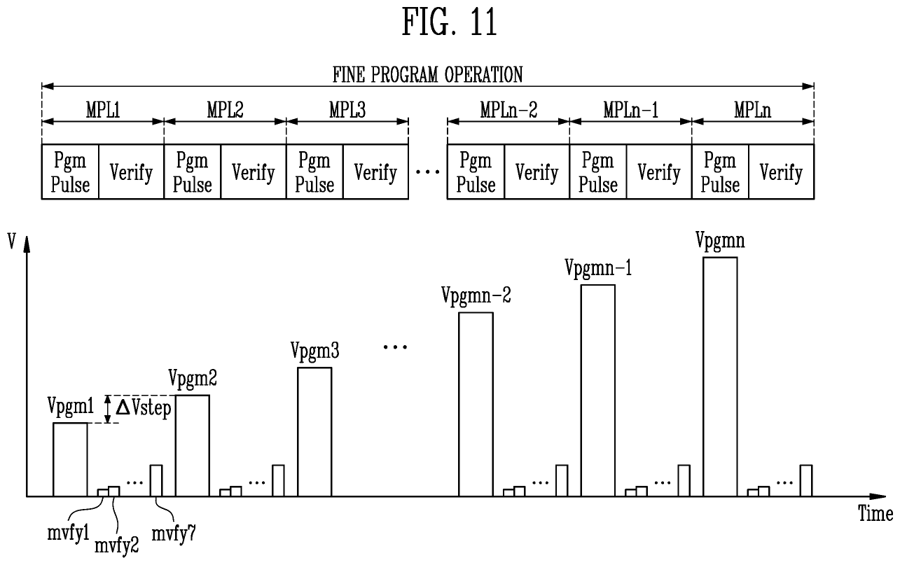

FIG. 11 is a diagram illustrating an embodiment of a fine program operation including a plurality of fine program loops.

In FIG. 11, the horizontal axis of a graph represents time Time, and the vertical axis of the graph represents voltage V applied to a word line. The voltage V applied to the word line may include a fine program voltage Vpgm and a fine verify voltage mvfy.

Referring to FIG. 11, the memory device 100 may perform the foggy program operation and then perform a fine program operation. The fine program operation may include a plurality of fine program loops MPL1 to MPLn. Each of the plurality of fine program loops MPL1 to MPLn may include a fine program voltage apply operation Pgm Pulse and a fine verify operation Verify.

The fine program voltage apply operation Pgm Pulse may be an operation of applying a fine program voltage Vpgm to a selected word line to which selected memory cells are connected. The fine verify operation Verify may be an operation of applying a fine verify voltage mvfy to the selected word line to which the selected memory cells are connected.

In an embodiment, in a first fine program loop MPL1, the memory device 100 may apply a first fine program voltage Vpgm1 to a selected word line to which selected memory cells are connected, and then apply first to seventh fine verify voltages mvfy1 to mvfy7 to the selected word line. The memory device 100 may apply, to the selected word line, a fine verify voltage corresponding to a target program state of memory cells among the first to seventh fine verify voltages mvfy1 to mvfy7. For example, the memory device 100 may perform a fine verify operation Verify on memory cells of which target program state is a first fine program state by using the first fine verify voltage mvfy1. The number of fine verify voltages is not limited to this embodiment.

It may be decided that a threshold voltage of memory cells on which the fine verify operation Verify passes by using each of the fine verify voltages mvfy1 to mvfy7 has a threshold voltage corresponding to a target program state. The program inhibit voltage may be applied to bit lines connected to the memory cells on which the fine verify operation Verify passes.

It may be decided that a threshold voltage of memory cells on which the fine verify operation Verify passes by using each of the fine verify voltages mvfy1 to mvfy7 does not have the threshold voltage corresponding to the target program state. A second fine program loop MPL2 may be performed on the memory cells on which the fine verify operation Verify fails. The program allow voltage may be applied to bit lines connected to the memory cells on which the fine verify operation Verify fails.

In the second fine program loop MPL2, the memory device 100 may apply a second fine program voltage Vpgm2 higher by a step voltage ΔVstep than the first fine program voltage Vpgm1 to a selected word line to which selected memory cells are connected. After that, the memory device 100 may perform a fine verify operation Verify of the second fine program loop MPL2, identically to the fine verify operation Verify of the first fine program loop MPL1.

After that, the memory device 100 may perform next fine program loops, identically to the second fine program loop MPL2.

In an embodiment, when the fine program loop operation is not completed within the fine program loops by a predetermined number of times, the fine program operation may fail. When the fine program loop operation is completed within the fine program loops by the predetermined number of times, the fine program operation may pass. The predetermined number of times may be a maximum number of program loops. The maximum number of program loops may be determined at the manufacturing or design stage of the memory device. In an embodiment, the max program loop number may be determined when the memory device performs a program operation. When all fine verify operation Verify on selected memory cells passes, the fine program operation may be completed. When a fine verify operation Verify on all the selected memory cells passes, a next fine program loop might not be performed.

In an embodiment, a program voltage may be determined according to an Incremental Step Pulse Programming (ISPP) method. A level of the fine program voltage may stepwisely increase or decrease as the fine program loops MPL1 to MPLn are repeated. A number of times a fine program voltage used in each of the fine program loops is applied, a level of the fine program voltage, a time required to apply the fine program voltage, and the like may be determined in various forms under the control of the memory controller 200.

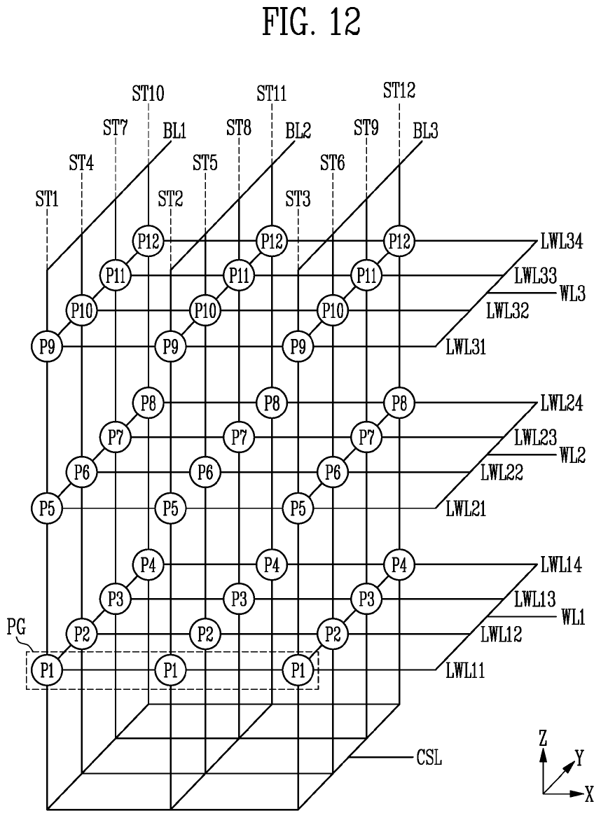

FIG. 12 is a diagram illustrating an embodiment of a structure of a three-dimensionally configured memory block.

Referring to FIG. 12, the memory block BLK shown in FIG. 2 may be a three-dimensionally configured memory block. The memory block may include a plurality of physical pages P1 to P12. Each of the plurality of physical pages P1 to P12 may include a plurality of memory cells. The plurality of physical pages P1 to P12 may be connected between bit lines BL1 to BL3 and a common source line CSL. One word line may be commonly connected to four local word lines. For example, a first word line WL1 may be commonly connected to eleventh to fourteenth local word lines LWL11 to LWL14. Memory cells may be connected to each of local lines. Memory cells connected to one local word line may constitute one physical page P. For example, memory cells connected to the eleventh local word line LWL11 may constitute a first physical page P1. One word line may include physical pages of which number corresponds to a number of local word lines commonly connected thereto.

A number of local word lines commonly connected to one word line may be determined according to a number of memory cell strings commonly connected to one bit line. For example, when four memory cell strings are commonly connected to one bit line, four local word lines may be commonly connected to one word line. The one word line may include four physical pages. The first word line WL1 may include first to fourth physical pages P1 to P4 respectively connected to the eleventh to fourteenth local word lines LWL11 to LWL14.

One memory cell string may include memory cells connected in series in a Z direction. Memory cell strings in a Y direction may be connected to one bit line. For example, a first memory cell string ST1, a fourth memory cell string ST4, a seventh memory cell string ST7, and a tenth memory cell string ST10 may be connected to a first bit line BL1.

In an embodiment, a plurality of logical page data may be stored in one physical page. A number of logical page data to be stored in one physical page may be determined according to a number of bit data stored by one memory cell. For example, when one memory cell stores four-bit data, a plurality of logical page data may include LSB page data, CSB page data, MSB page data, and QSB page data.

The number of each of the word lines, the local word lines, the memory cell strings, the bit lines, and the memory cells, which are shown in FIG. 12, is provided for convenience of description, and may be smaller or greater than the number shown in FIG. 12.

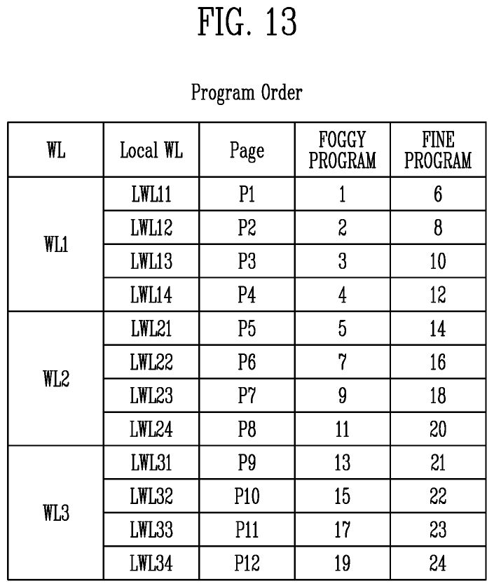

FIG. 13 is a diagram illustrating an embodiment of an order of a foggy program operation and a fine program operation.

FIG. 13 will be described with reference to FIG. 12. The memory device 100 may perform a foggy program operation and a fine program operation according to an order shown in FIG. 13. Memory cells connected to one local line Local WL may constitute one physical page.

First, the memory device 100 may sequentially perform the foggy program operation on the first to fourth physical pages P1 to P4 included in the first word line WL1. After that, the memory device 100 may perform the foggy program operation and the fine program operation while a second word line WL2 and the first word line WL1 are alternately selected. In an embodiment, the memory device 100 may perform the foggy program operation on a fifth physical page P5 and then perform the fine program operation on the first physical page P1. That is, the foggy program operation on each of fifth to eighth physical pages P5 to P8 and the foggy program operation on each of the first to fourth physical pages P1 to P4 may be alternately performed.

Like this, the memory device 100 may perform the foggy program operation and the fine program operation while a third word line WL3 and the second word line WL2 are alternately selected. The memory device 100 may perform the foggy program operation on a twelfth physical page P12 and then the fine program operation on the eighth physical page P8. That is, the memory device 100 may alternately perform the foggy program operation on each of ninth to twelfth physical pages P9 to P12 and the fine program operation on each of the fifth to eighth physical pages P5 to P8.

After that, when the foggy program operation on all physical pages is performed, the memory device 100 may sequentially perform the fine program operation on each of the ninth to twelfth physical pages P9 to P12 included in the third word line WL3 as the last word line.

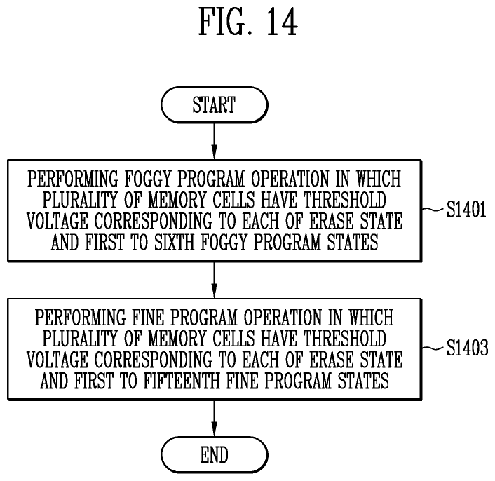

FIG. 14 is a flowchart illustrating an embodiment of a foggy program operation and a fine program operation.

Referring to FIG. 14, in Step S1401, the memory device 100 may perform a foggy program operation in which a plurality of memory cells have a threshold voltage corresponding to each of an erase state and first to sixth foggy program states.

In Step S1403, the memory device 100 may perform a fine program operation in which a plurality of memory cells have a threshold voltage corresponding to each of an erase state and first to fifteenth fine program states. In an embodiment, memory cells having a threshold voltage corresponding to each of the erase state and the first and second foggy program states may have a threshold voltage corresponding to each of the erase state and the first to eleventh fine program states in the fine program operation. In an embodiment, memory cells having a threshold voltage corresponding to each of the third to sixth foggy program states may have a threshold voltage corresponding to each of the twelfth to fifteenth fine program states in the fine program operation.

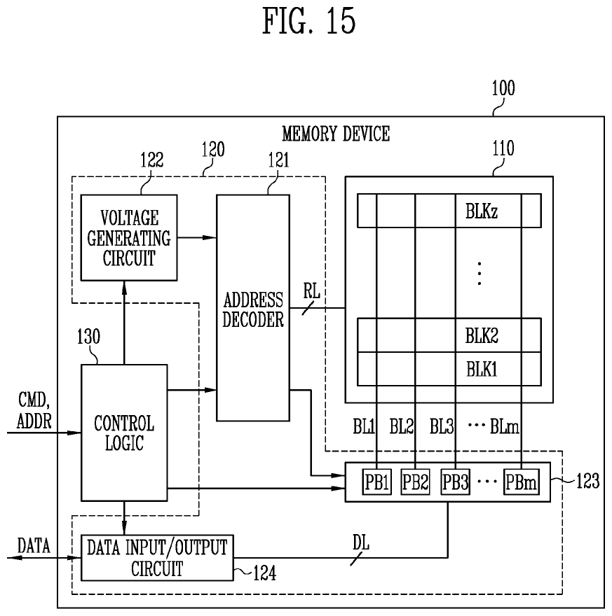

FIG. 15 is a diagram illustrating an embodiment of a structure of a memory device.

Referring to FIG. 15, the memory device 100 may include a memory cell array 110, a peripheral circuit 120, and control logic 130. The control logic 130 may be implemented as hardware, software, or a combination of hardware and software. For example, the control logic 130 may be a control logic circuit operating in accordance with an algorithm and/or a processor executing control logic code.

The memory cell array 110 may include a plurality of memory blocks BLK1 to BLKz. The plurality of memory blocks BLK1 to BLKz may be connected to an address decoder 121 through row lines RL. The plurality of memory blocks BLK1 to BLKz may be connected to a page buffer group 123 through bit lines BL1 to BLm. Each of the plurality of memory blocks BLK1 to BLKz may include a plurality of memory cells. In an embodiment, the plurality of memory cells may be nonvolatile memory cells.

The peripheral circuit 120 may drive the memory cell array 110. For example, the peripheral circuit 120 may drive the memory cell array 110 to perform a program operation, a read operation, and an erase operation under the control of the control logic 130. In another example, the peripheral circuit 120 may apply various operating voltages to the row lines RL and the bit lines BL1 to BLm or discharge the applied voltages under the control of the control logic 130.

The peripheral circuit 120 may include the address decoder 121, a voltage generating circuit 122, the page buffer group 123, and a data input/output circuit 124. The peripheral circuit 120 shown in FIG. 15 may be a component in which the address decoder 121 and the data input/output circuit 124 are further included in the peripheral circuit 180 shown in FIG. 2.

The address decoder 121 may be connected to the memory cell array 110 through the row lines RL. The row lines RL may include drain select lines, dummy word lines, a plurality of word lines, and source select lines.

The address decoder 121 may be operated under the control of the control logic 130. The address decoder 121 may receive an address from the control logic 130.

The address decoder 121 may decode a row address in the address. The address decoder 121 may select at least one word line WL of a selected memory block by applying voltages provided from the voltage generating circuit 122 to the at least one word line according to the row address.

The address decoder 121 may decode a column address in the address. The column address may be transferred to the page buffer group 123.

In a program operation, the address decoder 121 may apply a program voltage to the selected word line, and apply a pass voltage having a level lower than a level of the program voltage to unselected word lines. In a program verify operation, the address decoder 121 may apply a verify voltage to the selected word line, and apply a verify pass voltage having a level higher than a level of the verify voltage to the unselected word lines.

In a read operation, the address decoder 121 may apply a read voltage to the selected word line, and apply a read pass voltage having a level higher than a level of the read voltage to the unselected word lines. The voltage generating circuit 122 may generate a plurality of

operating voltages by using an external power voltage supplied to the memory device 100. The voltage generating circuit 122 may operate under the control of the control logic 130. In an embodiment, the voltage generating circuit 122 may include the voltage generating circuit shown in FIG. 2.

In an embodiment, the voltage generating circuit 122 may generate various operating voltages used for program, read, and erase operations. For example, the voltage generating circuit 122 may generate a plurality of erase voltages, a plurality of program voltages, a plurality of pass voltages, a plurality of select read voltages, and a plurality of unselect read voltages. The operating voltages may be supplied to the memory cell array 110 by the address decoder 121.

The page buffer group 123 may include first to mth page buffers PB1 to PBm. The first to mth page buffers PB1 to PBm may be connected to the memory cell array 110 respectively through first to mth bit lines BL1 to BLm. The first to mth page buffers PB1 to PBm may operate under the control of the control logic 130. The page buffer group 123 may include the page buffer group 160 shown in FIG. 2.

The first to mth page buffers PB1 to PBm may communicate data DATA with the data input/output circuit 124. In a program operation, the first to mth page buffers PB1 to PBm may receive data DATA to be stored through the data input/output circuit 124 and data lines DL.

In a program operation, the first to mth page buffers PB1 to PBm may transfer data received through the data input/output circuit 124 to selected memory cells through the bit lines BL1 to BLm. The selected memory cells may be programmed according to the transferred data. A memory cell connected to a bit line through which a program allow voltage (e.g., a ground voltage) is applied may have an increased threshold voltage. A threshold voltage of a memory cell connected to a bit line through which a program inhibit voltage (e.g., a power voltage) is applied may be maintained. In a verify operation, the first to mth page buffers PB1 to PBm may read data stored in the selected memory cells from the selected memory cells through the bit lines BL1 to BLm.

In a read operation, the page buffer group 123 may sense data from the memory cells of the selected word line through the bit lines BL1 to BLm, and store the sensed data in the first to mth page buffers PB1 to PBm.

The data input/output circuit 124 may be connected to the first to mth page buffers PB1 to PBm through the data lines DL. The data input/output circuit 124 may operate under the control of the control logic 130. In a program operation, the data input/output circuit 124 may receive data to be stored from the memory controller 200. In a read operation, the data input/output circuit 124 may output, to the memory controller 200, data sensed through the first to mth page buffers PB1 to PBm.

The control logic 130 may be connected to the address decoder 121, the voltage generator 122, the page buffer group 123, and the data input/output circuit 124. The control logic 130 may control a general operation of the memory device 100. The control logic 130 may operate in response to a command CMD transferred from the memory controller 200.

The control logic 130 may control the peripheral circuit 120 by generating several signals in response to a command CMD and an address ADDR. In an embodiment, the control logic 130 may include the program operation control circuit 170 shown in FIG. 2. In an embodiment, the control logic 130 may control the peripheral circuit 120 to perform a foggy program operation in which selected memory cells among the plurality of memory cells have a threshold voltage corresponding to each of an erase state and first to sixth foggy program states. The control logic 130 may control the peripheral circuit 120 to perform a fine program operation in which the selected memory cells on which the foggy program operation is performed have a threshold voltage corresponding to each of an erase state and first to fifteenth fine program states.

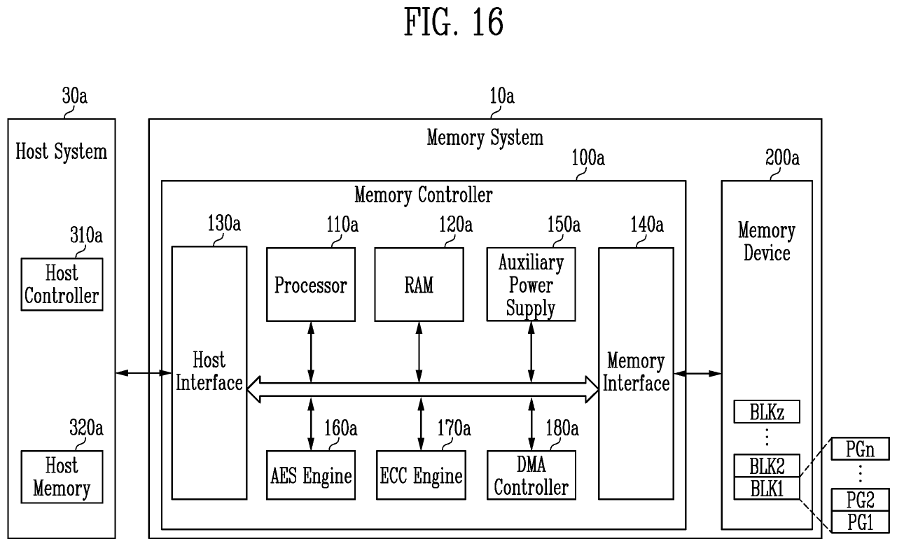

FIG. 16 is a diagram illustrating an embodiment of an electronic system including a memory system.

Referring to FIG. 16, the electronic system may include a memory system 10a and a host system 30a. In an embodiment, the memory system 50 shown in FIG. 1 may be implemented identically to the memory system 10a shown in FIG. 16.

The electronic system of the present disclosure may be implemented as any one of various types of electronic devices. For example, the electronic system may be implemented as a mobile phone, a Personal Computer (PC), a tablet PC, a wearable device, a healthcare device, an Internet of Things (IoT) device, a server device, a data center, an auto pilot, a Battery Management System (BMS), an electronic book (e-book), a game console device, a smart television, a digital camera, an artificial intelligence learning device, or the like.

The host system 30a may include a host controller 310a and a host memory 320a. In an embodiment, the host controller 310a and the host memory 320a may be implemented into a separate semiconductor package chip. In another embodiment, the host controller 310a and the host memory 320a may be implemented into one integrated semiconductor package chip.

The host controller 310a may provide a memory controller 100a with a request related to data. For example, the host controller 310a may provide a write request, data, and an address to the memory controller 100a to store the data. The host controller 310a may provide a read request and an address to the memory controller 100a to read the data. The host controller 310a may provide an erase request and an address to the memory controller 100a to erase the data.

The host memory 320a may store data to be transmitted to the memory controller 100a or data received from the memory controller 100a. The host memory 320a may be implemented as a Static Random Access Memory (SRAM), a Dynamic RAM (DRAM), or the like.

The memory system 10a may include the memory controller 100a and at least one memory device 200a. The memory controller 100a may control the memory device 200a.

The memory controller 100a may include a processor 110a, a RAM 120a, a host interface 130a, a memory interface 140a, an auxiliary power supply 150a, an Advanced Encryption Standard (AES) engine 160a, an Error Correction Code (ECC) engine 170a, and a Direct Memory Access (DMA) controller 180a, and the processor 110a, the RAM 120a, the host interface 130a, the memory interface 140a, the auxiliary power supply 150a, the AES engine 160a, the ECC engine 170a, and the DMA controller 180a may communicate with each other through a bus.

The processor 110a may operate as a central processing unit. The processor 110a may control overall operations of the memory controller 100a.

The processor 110a may generate a command to control an operation of the memory device 200a, and provide the command to the memory device 200a through the memory interface 140a. Specifically, the processor 110a may generate a read command when a read request is received from the host system 30a, generate a program command when a write request is received from the host system 30a, and generate an erase command when an erase request is received from the host system 30a.

The processor 110a may perform a function of a Flash Translation Layer (FTL). Specifically, the processor 110a may translate a logical address received from the host system 30a into a physical address. The physical address may be an address representing a position of a storage area of the memory device 200a.

The RAM 120a may operate as a buffer memory. For example, the RAM 120 may store data received from the host system 30a or data received from the memory device 200a.

The host interface 130a may communicate with the host system 30a. Specifically, the host interface 130a may receive a request and a logical address from the host system 30a. The host interface 130a may receive data from the host system 30a or transmit data to the host system 30a.

The memory interface 140a may communicate with the memory device 200a. Specifically, the memory interface 140a may transmit a program command, a physical address, and data to the memory device 200a. The memory interface 140a may transmit a read command and physical address to the memory device 200a, and receive data output from the memory device 200a. The memory interface 140a may transmit an erase command and a physical address to the memory device 200a. To this end, the memory interface 140a may be connected to the memory device 200a through a channel.

The auxiliary power supply 150a may be connected to the host system 30a through a connector. The auxiliary power supply 150a may periodically check a level of a power source supplied from the host system 30a. The auxiliary power supply 150a may supply an auxiliary power source to the memory system 10a when it is decided that Sudden Power Off (SPO) occurs according to the level of the power source.

The AES engine 160a may code or decode data, using an AES algorithm. The AES algorithm may be a symmetric key algorithm using the same encryption key in a coding operation and a decoding operation.

The ECC engine 170a may perform an error detection operation and an error correction operation on data. Specifically, the ECC engine 170a may generate parity data about data to be stored in the memory device 200a.

The DMA controller 180a may directly access the host memory 320a of the host system 30a. For example, separately from the host controller 310a, the DMA controller 180a may fetch data stored in the host memory 320a or store data in the host memory 320a.

In accordance with an embodiment of the present disclosure, there can be provided a memory device and an operating method thereof, which can improve a threshold voltage distribution of memory cells in a program operation.

While the present disclosure has been shown and described with reference to certain embodiments thereof, it will be understood by those skilled in the art that various changes in form and details may be made therein without departing from the spirit and scope of the present disclosure as defined by the appended claims and their equivalents. Therefore, the scope of the present disclosure should not be limited to the above-described embodiments but should be determined by not only the appended claims but also the equivalents thereof.

In the above-described embodiments, all steps may be selectively performed or part of the steps and may be omitted. In each embodiment, the steps are not necessarily performed in accordance with the described order and may be rearranged. The embodiments disclosed in this specification and drawings are only examples to facilitate an understanding of the present disclosure, and the present disclosure is not limited thereto. That is, it should be apparent to those skilled in the art that various modifications can be made on the basis of the technological scope of the present disclosure.

Meanwhile, the embodiments of the present disclosure have been described in the drawings and specification. Although specific terminologies are used here, those are only to explain the embodiments of the present disclosure. Therefore, the present disclosure is not restricted to the above-described embodiments and many variations are possible within the spirit and scope of the present disclosure. It should be apparent to those skilled in the art that various modifications can be made on the basis of the technological scope of the present disclosure in addition to the embodiments disclosed herein.

What is claimed is:

1. A memory device comprising:
a plurality of memory cells;
a peripheral circuit configured to perform a program operation of storing data in the plurality of memory cells; and
a program operation control circuit configured to, in the program operation, control the peripheral circuit to perform a foggy program operation of increasing a threshold voltage of the plurality of memory cells to a threshold voltage corresponding to any one state among an erase state and first to sixth foggy program states, and perform a fine program operation of increasing the threshold voltage of the plurality of memory cells to any one state among the erase state and first to fifteenth fine program states.

2. The memory device of claim 1, wherein the program operation control circuit controls the peripheral circuit such that, in the fine program operation, first memory cells having a threshold voltage corresponding to each of the erase state and the first and second foggy program states among the plurality of memory cells have a threshold voltage corresponding to each of the erase state and the first to eleventh fine program states.

3. The memory device of claim 1, wherein the program operation control circuit controls the peripheral circuit such that, in the fine program operation, second memory cells having a threshold voltage corresponding to each of the third to sixth foggy program states among the plurality of memory cells have a threshold voltage corresponding to each of the twelfth to fifteenth fine program states, respectively.

4. The memory device of claim 1, wherein the program operation control circuit controls the peripheral circuit such that, in the fine program operation, third memory cells having a threshold voltage corresponding to the second foggy program state among the plurality of memory cells have a threshold voltage corresponding to each of the eighth to eleventh fine program states.

5. The memory device of claim 1, wherein the program operation control circuit controls the peripheral circuit to perform the foggy program operation by using foggy verify voltages corresponding to the first to sixth foggy program states.

6. The memory device of claim 5, wherein the program operation control circuit controls the peripheral circuit to perform the fine program operation when foggy verify operations using the foggy verify voltages pass.

7. The memory device of claim 1, wherein the program operation control circuit controls the peripheral circuit to perform the foggy program operation on memory cells connected to a word line adjacent to a word line connected to the plurality of memory cells before the fine program operation on the plurality of memory cells is performed.

8. The memory device of claim 1, wherein the program operation control circuit controls the peripheral circuit to perform the fine program operation by using a plurality of logical page data received from an external device.

9. The memory device of claim 8, wherein the program operation control circuit controls the peripheral circuit to read first and second logical page data among the plurality of logical page data from the plurality of memory cells in the fine program operation.

10. The memory device of claim 9, wherein the program operation control circuit controls the peripheral circuit to perform the fine program operation by the first and second logical page data and third and fourth logical page data received from the external device among the plurality of logical page data.

11. A memory device comprising:
a plurality of memory cells;
a peripheral circuit configured to perform a program operation of increasing a threshold voltage of the plurality of memory cells; and
a program operation control circuit configured to, in the program operation, control the peripheral circuit to perform a foggy program operation of increasing the threshold voltage of the plurality of memory cells to a threshold voltage corresponding to each of first to sixth foggy program states, and perform a fine program operation of increasing a threshold voltage of first memory cells corresponding to the first foggy program state or the second foggy program state among the plurality of memory cells to a threshold voltage corresponding to each of fourth to seventh fine program states or each of eighth to eleventh fine program states among an erase state and first to fifteenth fine program states and increasing a threshold voltage of second memory cells corresponding to each of the third to sixth foggy program states among the plurality of memory cells to a threshold voltage corresponding to each of the twelfth to fifteenth fine program states.

12. The memory device of claim 11, wherein the program operation control circuit controls the peripheral circuit such that, in the fine program operation, a threshold voltage of third memory cells corresponding to the erase state among the plurality of memory cells increases to a threshold voltage corresponding to each of the erase state and the first to third fine program states.

13. The memory device of claim 11, wherein the program operation control circuit includes a word line control circuit configured to control the peripheral circuit to apply foggy verify voltages corresponding to the first to sixth foggy program states to a word line connected to the plurality of memory cells in the foggy program operation.

14. The memory device of claim 13, wherein the word line control circuit controls the peripheral circuit to apply a fine program voltage to the word line after foggy verify operations using the foggy verify voltages pass.

15. The memory device of claim 11, wherein the program operation control circuit controls the peripheral circuit to perform the fine program operation on memory cells connected to a word line adjacent to a word line connected to the plurality of memory cells before the foggy program operation on the plurality of memory cells is performed.

16. The memory device of claim 11, wherein the program operation control circuit controls the peripheral circuit to perform the foggy program operation by using first to fourth logical page data received from an external device.

17. The memory device of claim 11, wherein the program operation control circuit controls the peripheral circuit to perform the fine program operation by using first and second logical page data read from the plurality of memory cells and third and fourth logical page data received from the external device.

18. A method of operating a memory device, the method comprising:
performing a foggy program operation of increasing a threshold voltage of a plurality of memory cells to a threshold voltage corresponding to any one state among an erase state and first to sixth foggy program states; and
performing a fine program operation of increasing the threshold voltage of the plurality of memory cells to a threshold voltage corresponding to any one state among the erase state and first to fifteenth fine program states.

19. The method of claim 18, wherein, in the performing of the fine program operation, a threshold voltage of first memory cells, which corresponds to each of the erase state and the first and second foggy program states, among the plurality of memory cells increases to a threshold voltage corresponding to each of the erase state and the first to eleventh fine program states.

20. The method of claim 18, wherein, in the performing of the fine program operation, a threshold voltage of second memory cells, which corresponds to each of the third to sixth foggy program states, among the plurality of memory cells increases to a threshold voltage corresponding to each of the twelfth to fifteenth fine program states, respectively.
